(19) United States
(12) Patent Application Publication
(10) Pub. No.: US 2017/0047363 A1
(43) Pub. Date: Feb. 16, 2017

(54) AUTO-FOCUS IMAGE SENSOR

(71) Applicant: Samsung Electronics Co., Ltd., Suwon-si (KR)

(72) Inventors: Hyuk Soon Choi, Hwaseong-si (KR); Kyungho Lee, Suwon-si (KR)

(21) Appl. No.: 15/233,378

(22) Filed: Aug. 10, 2016

(30) Foreign Application Priority Data
Aug. 11, 2015 (KR) 10-2015-0113228

(51) Int. Cl. H01L 27/146

(52) U.S. Cl. CPC H01L 27/1463; H01L 27/14643; H01L 27/14636; H01L 27/1462; H01L 27/14605

(57) ABSTRACT

An auto-focus image sensor includes a substrate including unit pixels and having first and second surfaces facing each other, a pixel separation part passing through the substrate from the first surface to the second surface and separating the unit pixels from each other, at least one pair of photoelectric conversion parts provided in each of the unit pixels of the substrate, and a sub-pixel separation part provided in the substrate and interposed between the at least one pair of the photoelectric conversion parts. The second surface serves as a light-receiving surface.

### CROSS-REFERENCE TO RELATED APPLICATIONS

This U.S. non-provisional patent application claims priority under 35 U.S.C. §119 to Korean Patent Application No. 10-2015-0113228, filed on Aug. 11, 2015, in the Korean Intellectual Property Office, the entire contents of which are hereby incorporated by reference.

### BACKGROUND OF THE INVENTION

Example embodiments of the inventive concept relate to an auto-focus image sensor, and, in particular, to an auto-focus image sensor using a detected phase.

To realize an auto-focusing function in a digital image processing device (e.g., cameras), it may be necessary to detect a focus state of an imaging lens. A conventional digital image processing device is configured to include a focus detecting device in addition to an image sensor. However, because the focus detecting device or an additional lens therefor is needed, it may be difficult to reduce cost and size of the digital image processing device. To overcome this difficulty, an auto-focus image sensor has been developed, which is configured to realize an auto-focus function using a difference in phase of an incident light.

### SUMMARY

According to example embodiments of the inventive concept, an auto-focus image sensor may include a substrate with unit pixels, the substrate having a first surface and a second surface facing the first surface and serving as a light-receiving surface, a pixel separation part provided in the substrate to separate the unit pixels from each other, at least one pair of photoelectric conversion parts provided in each of the unit pixels of the substrate, and a sub-pixel separation part interposed between the at least one pair of the photoelectric conversion parts that are positioned adjacent to each other. At least a portion of the pixel separation part may include a material whose refractive index is different from that of the substrate, and the sub-pixel separation part may include a portion that is configured to allow photo charges generated in the at least one pair of the photoelectric conversion parts to be transmitted therethrough.

In some embodiments, the pixel separation part may be configured to penetrate the substrate from the first surface to the second surface, the pixel separation part may include a first doped region adjacent to the first surface and a first deep device isolation layer adjacent to the second surface and in contact with the first doped region, the first doped region may be doped to have a first conductivity type, and the first deep device isolation layer may include a material whose refractive index is different from that of the substrate.

In some embodiments, each of the at least one pair of the photoelectric conversion parts may include a first impurity region, which is formed adjacent to the first surface and is doped to have the first conductivity type, and a second impurity region, which is formed spaced apart from the first surface and is doped to have a second conductivity type different from the first conductivity type. A top surface of the second impurity region adjacent to the second surface may be farther from the first surface than an interface between the first doped region and the first deep device isolation layer.

In some embodiments, the sub-pixel separation part may include a second doped region, which is disposed adjacent to the first surface and is doped to have the first conductivity type, and at least a portion of the second doped region may have a lower concentration of impurities of the first conductivity type, than the first doped region.

In some embodiments, the sub-pixel separation part may further include a second deep device isolation layer disposed adjacent to the second surface and in contact with the second doped region, and the second deep device isolation layer may include substantially the same material as the first deep device isolation layer.

In some embodiments, the sub-pixel separation part may further include a third doped region disposed adjacent to the second surface and in contact with the second doped region, and the third doped region may be doped to have the first conductivity type and may have a higher concentration of impurities of the first conductivity type than the at least a portion of the second doped region.

In some embodiments, the first deep device isolation layer may include a first insulating gapfill layer and a first poly silicon pattern disposed in the first insulating gapfill layer.

In some embodiments, the sub-pixel separation part may further include a second deep device isolation layer, which is disposed adjacent to the second surface and in contact with the second doped region, and the second deep device isolation layer may include a second insulating gapfill layer and a second poly silicon pattern disposed in the second insulating gapfill layer.

In some embodiments, the first deep device isolation layer may include a first insulating layer and a first fixed charge layer interposed between the first insulating layer and the substrate.

In some embodiments, the first fixed charge layer and the first insulating layer may be extended to cover the second surface, and the first fixed charge layer may be in contact with the second surface.

In some embodiments, the sub-pixel separation part may further include a second deep device isolation layer, which is disposed adjacent to the second surface and in contact with the second doped region, and the second deep device isolation layer may include a second insulating layer and a second fixed charge layer interposed between the second insulating layer and the substrate.

In some embodiments, each of the first and second fixed charge layers may be formed of a metal oxide or metal fluoride including at least one material selected from a group consisting of hafnium (Hf), zirconium (Zr), aluminum (Al), tantalum (Ta), titanium (Ti), yttrium (Y), tungsten (W), and lanthanoids.

In some embodiments, the pixel separation part may include a first deep device isolation layer adjacent to the second surface and a third deep device isolation layer adjacent to the first surface and in contact with the first deep device isolation layer.

In some embodiments, the first deep device isolation layer may be disposed in a first deep trench, which is formed to penetrate the substrate in a direction from the second surface toward the first surface, and the third deep device isolation layer may be disposed in a third deep trench, which is formed to penetrate the substrate in a direction from the first surface toward the second surface.

In some embodiments, the sub-pixel separation part may include a second doped region, which is disposed adjacent to the first surface and is doped to have a first conductivity type, and a second deep device isolation layer, which is disposed adjacent to the second surface and in contact with the second doped region. The second deep device isolation layer may include substantially the same material as the first deep device isolation layer.

In some embodiments, an interface between the first deep device isolation layer and the third deep device isolation layer may be closer to the second surface than a bottom surface of the second deep device isolation layer in contact with the second doped region.

In some embodiments, the first deep device isolation layer may include a first insulating layer and a first fixed charge layer interposed between the first insulating layer and the substrate, and the third deep device isolation layer may include a third insulating gapfill layer and a third poly silicon pattern disposed in the third insulating gapfill layer.

In some embodiments, the auto-focus image sensor may further include a fixed charge layer disposed on the second surface.

In some embodiments, the image sensor may further include color filters, which are provided on the unit pixels, respectively, and the second surface, and micro lenses, which are respectively provided on the color filters. Each of the micro lenses may be disposed to overlap the at least one pair of the photoelectric conversion parts of each of the unit pixels.

In some embodiments, the sub-pixel separation part may be disposed to penetrate the substrate from the first surface to the second surface.

According to example embodiments of the inventive concept, an auto-focus image sensor may include a substrate having first and second surfaces facing each other, the substrate including unit pixels, each of which includes at least one pair of sub-pixels configured to detect a difference in phase of light to be incident through the second surface, a photoelectric conversion part provided in each of the at least one pair of the sub-pixels of the substrate, a pixel separation part configured to penetrate the substrate from the first surface to the second surface and to separate the unit pixels from each other, a sub-pixel separation part configured to penetrate the substrate from the first surface to the second surface and to separate the at least one pair of the sub-pixels from each other, and a fixed charge layer on the second surface. At least a portion of the pixel separation part may include a material whose refractive index is different from that of the substrate, and each of the unit pixels may be configured to collectively process electrical signals, which are respectively output from the at least one pair of the sub-pixels, to obtain image information.

In some embodiments, the pixel separation part may include a first doped region adjacent to the first surface and a first deep device isolation layer adjacent to the second surface and in contact with the first doped region, the first doped region may be doped to have a first conductivity type, and the first deep device isolation layer may include a material whose refractive index is different from that of the substrate.

In some embodiments, the sub-pixel separation part may include a second doped region, which is disposed adjacent to the first surface and is doped to have the first conductivity type, and a second deep device isolation layer, which is disposed adjacent to the second surface and in contact with the second doped region. At least a portion of the second doped region may have a lower concentration of impurities of the first conductivity type than the first doped region.

In some embodiments, the second deep device isolation layer may include substantially the same material as the first deep device isolation layer.

In some embodiments, the sub-pixel separation part may be configured to allow photo charges generated in the at least one pair of the photoelectric conversion parts to be transmitted through the at least a portion of the second doped region.

In some embodiments, the fixed charge layer may include at least a portion interposed between the substrate and the first and second deep device isolation layers.

In some embodiments, each of the first and second deep device isolation layers may include a poly silicon pattern.

In some embodiments, the pixel separation part may include a first deep device isolation layer adjacent to the second surface and a third deep device isolation layer adjacent to the first surface and in contact with the first deep device isolation layer, and each of the first deep device isolation layer and the third device isolation layer may include a material whose refractive index is different from that of the substrate.

In some embodiments, the sub-pixel separation part may include a second doped region, which is disposed adjacent to the first surface and is doped to have a first conductivity type, and a second deep device isolation layer, which is disposed adjacent to the second surface and in contact with the second doped region. The second deep device isolation layer may include substantially the same material as the first deep device isolation layer.

According to further embodiments of the inventive concept, an auto-focus image sensor, comprises a substrate having a unit pixel disposed therein, the unit pixel comprising first and second photoelectric conversion parts, and a separation part disposed between the first and second photoelectric conversion parts that is configured to provide a current path for charge to transfer between the first and second photoelectric conversion parts responsive to incident light received at the unit pixel.

In other embodiments, separation part comprises a doped region and an isolation layer disposed on the doped region. The doped region is configured to provide the current path for the charge to transfer between the first and second photoelectric conversion parts.

In still other embodiments, the doped region comprises a first portion and a second portion comprising a plurality of layers, the first portion being disposed between ones of the plurality of layers of the second portion. The first portion has a doping concentration that is less than a doping concentration of the second portion.

In still other embodiments, the auto-focus image sensor further comprises a unit pixel isolation region that surrounds the unit pixel when the substrate is viewed from a plan view. The doping concentration of the first portion of the doped region is less than a doping concentration of the unit pixel isolation region.

In still other embodiments, each of the first and second photoelectric conversion parts comprises a first impurity region and a second impurity region disposed on the first impurity region. The first and second impurity regions have different conductivity types.

It is noted that aspects described with respect to one embodiment may be incorporated in different embodiments although not specifically described relative thereto. That is, all embodiments and/or features of any embodiments can be implemented separately or combined in any way and/or combination. Moreover, other methods, systems, and/or devices according to embodiments of the inventive concept will be or become apparent to one with skill in the art upon review of the following drawings and detailed description. It is intended that all such additional systems, methods, articles of manufacture, and/or devices be included within this description, be within the scope of the present inventive subject matter, and be protected by the accompanying claims.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic block diagram illustrating a digital image processing device according to example embodiments of the inventive concept.

FIG. 2 is a schematic block diagram illustrating an auto-focus image sensor according to example embodiments of the inventive concept.

FIGS. 3A and 3B are circuit diagrams illustrating auto-focus image sensors according to example embodiments of the inventive concept.

FIG. 4 is a plan view schematically illustrating an auto-focus image sensor according to example embodiments of the inventive concept.

FIG. 5 is a sectional view taken along line I-I′ of FIG. 4 to illustrate an auto-focus image sensor according to example embodiments of the inventive concept.

FIGS. 6A and 7A are plan views each illustrating a sub-pixel separation part of a unit pixel of an auto-focus image sensor of FIG. 4.

FIGS. 6B and 7B are sectional views taken along line II-II′ of FIGS. 6A and 7A, respectively.

FIG. 8 is a schematic diagram illustrating a phase-difference auto-focus operation of an auto-focus image sensor.

FIG. 9A is a graph illustrating a spatial variation in phase of signals that are output from sub-pixels in an out-of-focus state.

FIG. 9B is a graph illustrating a spatial variation in phase of signals that are output from sub-pixels in an in-focus state.

FIGS. 10 through 15 are sectional views taken along line I-I′ of FIG. 4 to illustrate a method of fabricating an auto-focus image sensor, according to example embodiments of the inventive concept.

FIG. 16 is a sectional view taken along line I-I′ of FIG. 4 to illustrate an auto-focus image sensor according to example embodiments of the inventive concept.

FIG. 17 is a sectional view taken along line I-I′ of FIG. 4 to illustrate an auto-focus image sensor according to example embodiments of the inventive concept.

FIG. 18 is a sectional view taken along line I-I′ of FIG. 4 to illustrate an auto-focus image sensor according to example embodiments of the inventive concept.

FIG. 19 is a sectional view taken along line I-I′ of FIG. 4 to illustrate an auto-focus image sensor according to example embodiments of the inventive concept.

FIG. 20 is a sectional view taken along line I-I′ of FIG. 4 to illustrate an auto-focus image sensor according to example embodiments of the inventive concept.

FIG. 21 is a sectional view taken along line I-I′ of FIG. 4 to illustrate an auto-focus image sensor according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and this specification and will not be interpreted in an idealized or overly formal sense unless expressly so defined herein.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

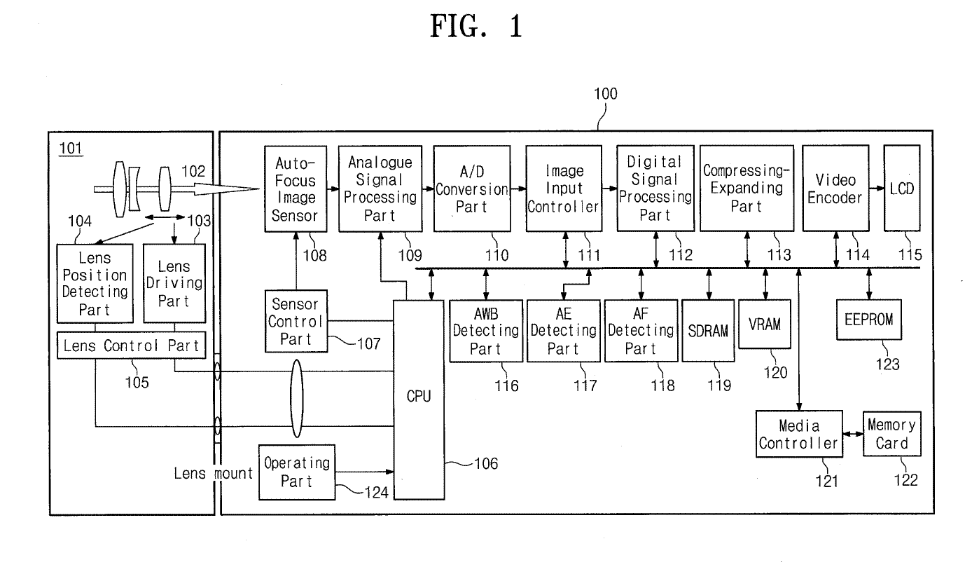

FIG. 1 is a schematic block diagram illustrating a digital image processing device according to example embodiments of the inventive concept.

As shown in FIG. 1, a digital image processing device 100 may be configured to be separable from a lens, but example embodiments of the inventive concept may not be limited thereto. For example, in the digital image processing device 100, an auto-focus image sensor 108 and the lens may be configured to form a single body. The use of the auto-focus image sensor 108 may make it possible to allow the digital image processing device 100 to have a phase-difference auto-focus (AF) function.

The digital image processing device 100 may include an imaging lens 101 provided with a focus lens 102. The digital image processing device 100 may be configured to drive the focus lens 102, and this may allow the digital image processing device 100 to have a focus detecting function. The imaging lens 101 may further include a lens driving part 103 configured to drive the focus lens 102, a lens position detecting part 104 configured to detect a position of the focus lens 102, and a lens control part 105 configured to control the focus lens 102. The lens control part 105 may be configured to exchange focus data with a central processing unit (CPU) 106 of the digital image processing device 100.

The digital image processing device 100 may include the auto-focus image sensor 108, which may be configured to produce an image signal from light incident through the imaging lens 101. The auto-focus image sensor 108 may include a plurality of photoelectric conversion parts (not shown), which are arranged in a matrix form, and a plurality of transmission lines (not shown), which are configured to transmit charges constituting the image signal from the photoelectric conversion parts.

The digital image processing device 100 may include a sensor control part 107 configured to generate a timing signal for controlling the auto-focus image sensor 108 when an image is taken. In addition, the sensor control part 107 may sequentially output image signals when a charging operation for each scanning line is finished.

The image signals may be transmitted into an analogue/digital (A/D) conversion part 110 through an analogue signal processing part 109. In the A/D conversion part 110, the image signals may be converted into digital signals, and the converted digital signals may be transmitted into and processed by an image input controller 111.

The digital image processing device 100 may further include auto-white balance (AWB), auto-exposure (AE), and auto-focus (AF) detecting parts 116, 117, and 118, which are respectively configured to perform AWB, AE, and AF operations, and the digital image signal input to the image input controller 111 may be used to perform the AWB, AE, and AF operations. During the phase-difference AF operation, information on pixels may be output from the AF detecting part 118 to the CPU 106 and then may be used to obtain a phase difference. For example, to obtain the phase difference, the CPU 106 may perform a correlation operation on a plurality of pixel column signals. The information on the phase difference may be used to obtain a position or direction of a focal point.

The digital image processing device 100 may further include a volatile memory device 119 (e.g., a synchronous dynamic random access memory (SDRAM)), which is configured to temporarily store the image signals. The digital image processing device 100 may include a digital signal processing part 112, which is configured to perform a series of image-signal processing steps (e.g., gamma correction) and to allow for a display of a live view or a capture image. The digital image processing device 100 may include a compressing-expanding part 113, which is configured to allow the image signal to be compressed in a compressed form (e.g., JPEG or H.264) or to be expanded when it is played. The digital image processing device 100 may include a media controller 121 and a memory card 122. An image file, in which the image signal compressed in the compression-expansion part 113 is contained, may be transmitted to the memory card 122 through the media controller 121.

The digital image processing device 100 may further include a video random access memory (VRAM) 120, a video encoder 114, and a liquid crystal display (LCD) 115. The video random access memory (VRAM) 120 may be configured to store information on images to be displayed, and the liquid crystal display (LCD) 115 may be configured to display the images transmitted from the VRAM 120 through a video encoder 114. The CPU 106 may serve as a controller for controlling overall operations of each part or component of digital image processing device 100. The digital image processing device 100 may further include an electrically erasable programmable read-only memory (EEPROM) 123, which is used to store and maintain various information used to correct or adjust defects in pixels of the auto-focus image sensor 108. The digital image processing device 100 may further include an operating part 124 for receiving various commands for operating the digital image processing device 100 from a user. The operating part 124 may include various buttons (not shown) (e.g., a shutter-release button, a main button, a mode dial, and a menu button).

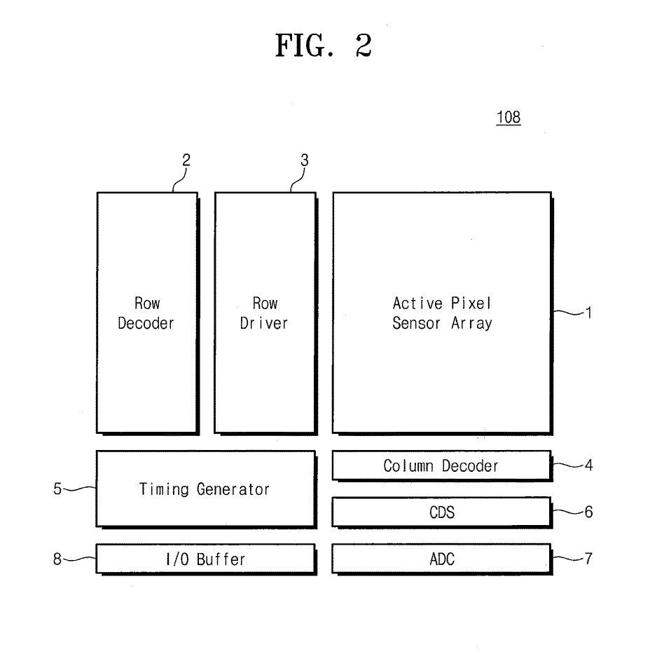

FIG. 2 is a schematic block diagram illustrating an auto-focus image sensor according to example embodiments of the inventive concept. Although a complementary metal-oxide-semiconductor (CMOS) image sensor is illustrated in FIG. 2, example embodiments of the inventive concept are not limited to the CMOS image sensor.

Referring to FIG. 2, the auto-focus image sensor 108 may include an active pixel sensor array 1, a row decoder 2, a row driver 3, a column decoder 4, a timing generator 5, a correlated double sampler 6, an analog-to-digital converter 7, and an input/output (I/O) buffer 8. The decoders 2 and 4, the row driver 3, the timing generator 5, the correlated double sampler 6, the analog-to-digital converter 7, and the I/O buffer 8 may constitute a peripheral logic circuit.

The active pixel sensor array 1 may include a plurality of two-dimensionally arranged unit pixels, each of which is configured to convert optical signals into electrical signals. According to example embodiments of the inventive concept, each of the unit pixels may include at least one pair of sub-pixels, each of which includes a photoelectric conversion part. The active pixel sensor array 1 may be driven by a plurality of driving signals (e.g., pixel-selection, reset, and charge-transfer signals) to be transmitted from the row driver 3. The electrical signals converted by the unit pixels may be transmitted to the correlated double sampler (CDS) 6.

The row driver 3 may be configured to generate driving signals for driving the unit pixels, based on information decoded by the row decoder 2, and then to transmit such driving signals to the active pixel sensor array 1. When the unit pixels are arranged in a matrix form (i.e., in rows and columns), the driving signals may be provided to respective rows.

The timing generator 5 may be configured to provide timing and control signals to the row and column decoders 2 and 4.

The correlated double sampler 6 may be configured to perform holding and sampling operations on the electrical signals generated from the active pixel sensor array 1. For example, the correlated double sampler 6 may include a capacitor and a switch and may be configured to perform a correlated doubling sampling operation and to output analog sampling signals, where the correlated doubling sampling may include calculating a difference between a reference voltage representing a reset state of the unit pixels and an output voltage generated from incident light, and the analog sampling signals may be generated to include an effective signal component for the incident light. The correlated double sampler 6 may include a plurality of CDS circuits, which are respectively connected to column lines of the active pixel sensor array 1, and may be configured to output the analog sampling signal corresponding to the effective signal component to respective columns.

The analog-to-digital converter (ADC) 7 may be configured to convert the analog signal, which contains information on the difference level outputted from the correlated double sampler 6, to be converted into a digital signal.

The I/O buffer 8 may be configured to latch the digital signals and then to output the latched digital signals sequentially to an image signal processing part (not shown), based on information decoded by the column decoder 4.

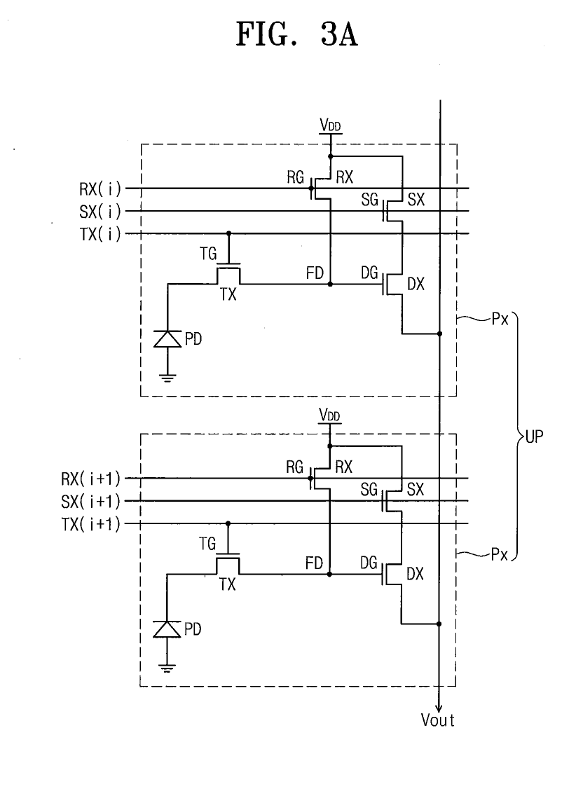

FIGS. 3A and 3B are circuit diagrams illustrating auto-focus image sensors according to example embodiments of the inventive concept.

Referring to FIG. 3A, each of the unit pixels UP of an auto-focus image sensor may include at least one pair of sub-pixels Px. The description that follows will refer to an example embodiment in which a pair of sub-pixels Px is provided in each unit pixel UP, but example embodiments of the inventive concept may not be limited thereto. The unit pixel UP may include at least two (e.g., four or six) sub-pixels Px.

Each of the sub-pixels Px may include a photoelectric conversion part PD, a transfer transistor TX, and logic transistors RX, SX, and DX. The logic transistors may include a reset transistor RX, a selection transistor SX, and a drive transistor or source follower transistor DX. The transfer transistor TX, the reset transistor RX, the selection transistor SX, and the drive transistor DX may include a transfer gate TG, a reset gate RG, a selection gate SG, and a drive gate DG, respectively. In addition, the transfer gate TG, the reset gate RG, and the selection gate SG may be respectively connected to signal lines (e.g., TX (i), RX (i), and SX (i)).

The photoelectric conversion part PD may be configured to allow photocharges to be generated proportional to an amount of external incident light and be accumulated. As an example, the photoelectric conversion part PD may include at least one of a photodiode, a photo transistor, a photo gate, a pinned photodiode (PPD), or any combination thereof. The transfer gate TG may be configured to transfer electric or photo charges accumulated in the photoelectric conversion part PD to a charge-detection node FD (i.e., a floating diffusion region). The photocharges transferred from the photoelectric conversion part PD may be cumulatively stored in the charge-detection node FD. The drive transistor DX may be controlled, depending on an amount of the photocharges stored in the charge detection node FD.

The reset transistor RX may be configured to periodically discharge the photocharges stored in the charge-detection node FD. The reset transistor RX may include drain and source electrodes, which are respectively connected to the charge-detection node FD and a node applied with a power voltage VDD. If the reset transistor RX is turned on, the power voltage VDD may be applied to the charge detection node FD through the source electrode of the reset transistor RX. Accordingly, the photocharges stored in the charge detection node FD may be discharged to the power voltage VDD through the reset transistor RX. In other words, the charge-detection node FD may be reset when the reset transistor RX is turned on.

The drive transistor DX, in conjunction with an electrostatic current source (not shown) outside the unit pixel UP, may serve as a source follower buffer amplifier. In other words, the drive transistor DX may be used to amplify a variation in electric potential of the charge detection node FD and output the amplified signal to an output line Vout.

The selection transistor SX may be used to select a row of the unit pixels UP to be read. When the selection transistor SX is turned on power voltage VDD may be transferred to the source electrode of the drive transistor DX.

In certain embodiments, as shown in FIG. 3B, at least one of the charge-detection node FD (or the floating diffusion region), the reset transistor RX, the selection transistor SX, and the drive transistor DX may be shared by adjacent ones of the sub-pixels Px, and this may make it possible for an image sensor to have an increased integration density.

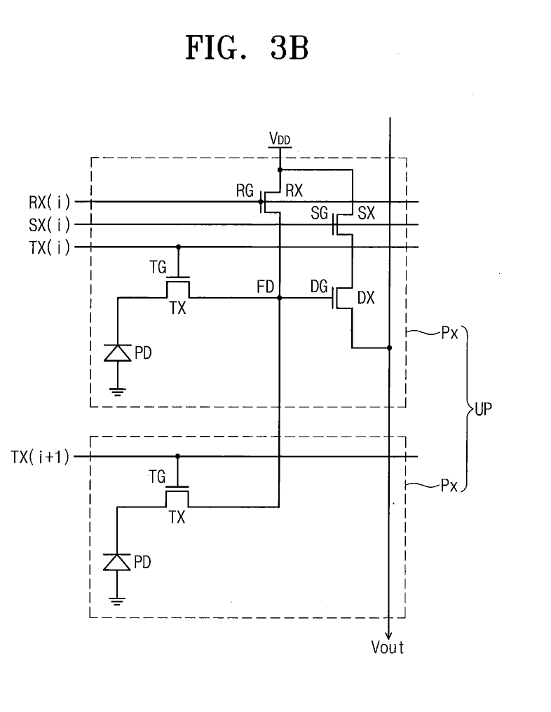

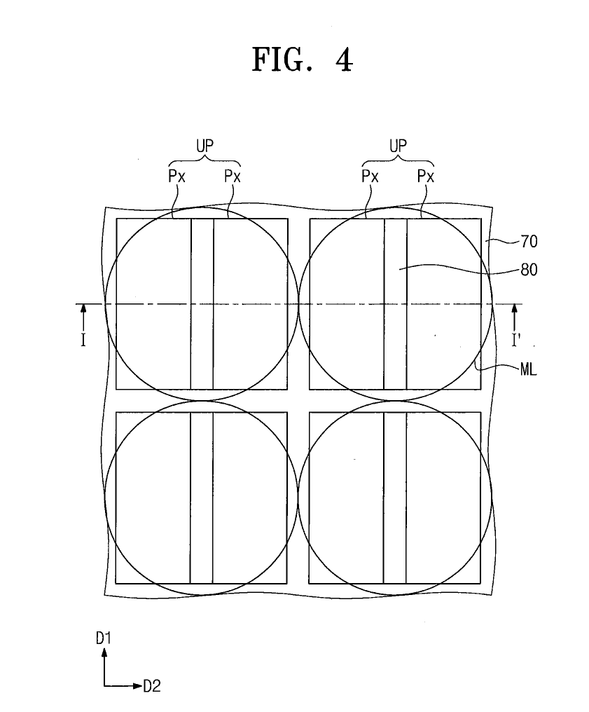

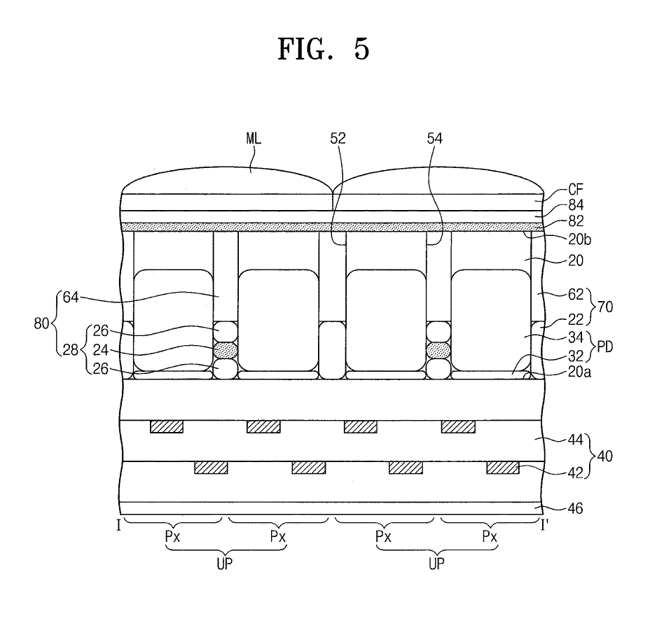

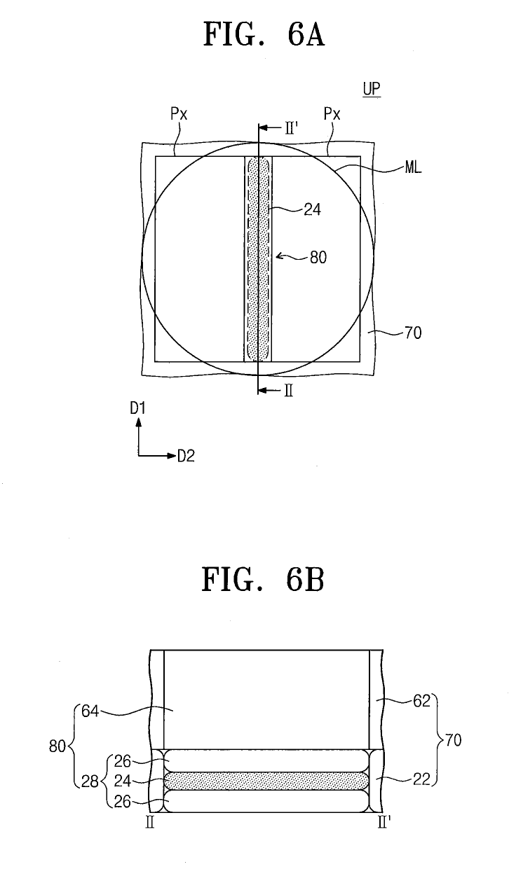

FIG. 4 is a plan view schematically illustrating an auto-focus image sensor according to example embodiments of the inventive concept. FIG. 5 is a sectional view taken along line I-I′ of FIG. 4 to illustrate an auto-focus image sensor according to example embodiments of the inventive concept. FIGS. 6A and 7A are plan views each illustrating a sub-pixel separation part of a unit pixel of an auto-focus image sensor of FIG. 4. FIGS. 6B and 7B are sectional views taken along line II-II′ of FIGS. 6A and 7A, respectively.

Referring to FIGS. 4 and 5, an auto-focus image sensor according to example embodiments of the inventive concept may include a substrate 20 provided with a plurality of the unit pixels UP. The substrate 20 may be a silicon wafer, a silicon-on-insulator (SOI) wafer, or an epitaxial semiconductor layer. The substrate 20 may have a first surface 20a and a second surface 20b facing each other. In some embodiments, the first surface 20a may be a front or top surface of the substrate 20 and the second surface 20b may be a back or bottom surface of the substrate 20. Light may be incident to the second surface 20b. In other words, the auto-focus image sensor according to example embodiments of the inventive concept may be a back-side light-receiving auto-focus image sensor.

A pixel separation part 70 may be provided in the substrate 20 to separate the unit pixels UP from each other. In a plan view, the pixel separation part 70 may be shaped like a mesh. For example, the pixel separation part 70 may be provided to enclose each of the unit pixels UP. The pixel separation part 70 may have a thickness that is substantially equal to that of the substrate 20. For example, the pixel separation part 70 may be provided to pass through the substrate 20 from the first surface 20a to the second surface 20b. In some embodiments, the pixel separation part 70 may include a first doped region 22, which is positioned adjacent to the first surface 20a, and a first deep device isolation layer 62, which is positioned adjacent to the second surface 20b to be in contact with the first doped region 22. The first doped region 22 may be doped with first conductivity type impurities (e.g., p-type impurities). The first deep device isolation layer 62 may be provided in a first deep trench 52, which may be formed to penetrate the substrate 20 in a direction from the second surface 20b of the substrate 20 toward the first surface 20a. The first deep device isolation layer 62 may be formed of or include an insulating material whose refractive index is different from that of the substrate 20. For example, the first deep device isolation layer 62 may be formed of or include at least one of silicon oxide, silicon nitride, or silicon oxynitride layer.

Each of the unit pixels UP may include a plurality of the sub-pixels Px, in each of which the photoelectric conversion part PD is provided. In other words, each of the unit pixels UP may include a plurality of the photoelectric conversion parts PD. Each of the sub-pixels Px may be configured to output an electrical signal. Each of the photoelectric conversion parts PD may include a first impurity region 32 adjacent to the first surface 20a of the substrate 20 and a second impurity region 34 spaced apart from the first surface 20a of the substrate 20. The first impurity region 32 may be doped with a first conductivity type impurities (e.g., p-type impurities), and the second impurity region 34 may be doped with a second conductivity type impurities (e.g., n-type impurities). A top surface of the second impurity region 34 adjacent to the second surface 20b may be farther from the first surface 20a than from an interface between the first doped region 22 and the first deep device isolation layer 62.

In each unit pixel UP, a sub-pixel separation part 80 may be provided in a region of the substrate 20 and between adjacent ones of the photoelectric conversion parts PD. In some embodiments, the sub-pixel separation part 80 may be a line-shaped structure extending in a first direction D1. In addition, the sub-pixel separation part 80 may be in contact with opposite sidewalls of the pixel separation part 70 parallel to the first direction D1. Accordingly, each of the unit pixels UP may be divided into a pair of the sub-pixels Px. The pair of the sub-pixels Px may be spaced apart from each other in a second direction D2 crossing the first direction D1. For example, in each unit pixel UP, the photoelectric conversion parts PD may be spaced apart from each other (e.g., with the sub-pixel separation part 80 interposed therebetween) in the second direction D2 or from side to side. The pixel separation part 70 may be provided between adjacent ones of the photoelectric conversion parts PD that are respectively included in different ones of the unit pixels UP. When viewed in a sectional view, each of the photoelectric conversion parts PD may be provided to be in contact with sidewalls of the pixel separation part 70 and the sub-pixel separation part 80 adjacent thereto. Accordingly, it is possible to increase an area of a light-receiving region and consequently to improve a full well capacity (FWC) property of the photoelectric conversion part PD. Although an example in which each of the unit pixels UP includes a pair of the sub-pixels Px has been described, example embodiments of the inventive concept may not be limited thereto. For example, in the case where each of the unit pixels UP is configured to include four or more sub-pixels Px, a planar shape of the sub-pixel separation part 80 may be variously changed.

The sub-pixel separation part 80 may have a thickness that is substantially equal to that of the substrate 20, similar to the pixel separation part 70. For example, the sub-pixel separation part 80 may be provided to pass through the substrate 20 from the first surface 20a to the second surface 20b. In some embodiments, the sub-pixel separation part 80 may include a second doped region 28, which is provided adjacent to the first surface 20a, and a second deep device isolation layer 64, which is provided adjacent to the second surface 20b to be in contact with the second doped region 28. The second doped region 28 may be doped with first conductivity type impurities (e.g., p-type impurities). In some embodiments, the second doped region 28 may include a plurality of stacked impurity regions. As an example, the second doped region 28 may include a first portion 24, which is lightly doped with first conductivity type impurities, and second portions 26, which are heavily doped with first conductivity type impurities to have a higher impurity concentration than the first portion 24. The first portion 24 may be spaced apart from the first surface 20a and the second portions 26 may be respectively provided on and below the first portion 24. In some embodiments, the first portion 24 may have an impurity concentration lower than that of the first doped region 22. This may make it possible to allow a portion (e.g., the first portion 24) of the second doped region 28 to form a lowered potential barrier with respect to the second impurity region 34 (of the second conductivity type) of the photoelectric conversion part PD, compared with other portion (e.g., the first doped region 22). In other words, the first portion 24 may serve as a current path, allowing photo charges (i.e., electrons) to be transferred from one of the photoelectric conversion parts PD to another. This will be described in more detail below. In certain embodiments, the second portions 26 may be provided to have an impurity concentration that is lower than or substantially equal to that of the first doped region 22.

The shape or disposition of the first portion 24 may be variously changed, and this may make it possible to variously change a size or position of the current path for the transmission of the photo charges. In some embodiments, as shown in FIGS. 6A and 6B, the first portion 24 may extend along the first direction D1 and may have end portions that are in contact with sidewalls of the pixel separation part 70. In some embodiments, as shown in FIGS. 7A and 7B, the first portion 24 may include an end portion in contact with a sidewall of the pixel separation part 70 and an opposite end portion spaced apart from the other sidewall of the pixel separation part 70. In this case, the second portion 26 may be provided between the opposite end portion of the first portion 24 and the other sidewall of the pixel separation part 70. In certain embodiments, although not shown, the first portion 24 may have opposite end portions that are spaced apart from the opposite sidewalls of the pixel separation part 70. In this case, the second portions 26 may be provided between the opposite end portions of the first portion 24 and sidewalls of the pixel separation part 70 adjacent thereto.

The second deep device isolation layer 64 may be provided in a second deep trench 54, which may be formed to penetrate the substrate 20 in a direction from the second surface 20b of the substrate 20 toward the first surface 20a. The second deep device isolation layer 64 may be formed of or include an insulating material whose refractive index is different from that of the substrate 20. The second deep device isolation layer 64 may be formed of or include at least one of silicon oxide, silicon nitride, or silicon oxynitride layer.

An interconnection structure 40 may be provided on the first surface 20a of the substrate 20. The interconnection structure 40 may include a plurality of stacked interlayered insulating layers 44 and a plurality of stacked interconnection layers 42. Although not shown, the transistors TX, RX, SX, and DX described with reference to FIG. 3A or FIG. 3B may be provided on the first surface 20a to detect and transfer electric charges generated in the photoelectric conversion part PD. A protection layer 46 may be provided below the lowermost one of the interlayered insulating layers 44. In certain embodiments, the protection layer 46 may be a passivation layer and/or a supporting substrate.

A fixed charge layer 82 may be provided on the second surface 20b of the substrate 20. The fixed charge layer 82 may be formed of an oxygen-containing metal layer, whose oxygen content is lower than its stoichiometric ratio, or a fluorine-containing metal layer, whose fluorine content ratio is lower than its stoichiometric ratio. For example, the fixed charge layer 82 may have negative fixed charges. The fixed charge layer 82 may be formed of a metal oxide or metal fluoride including at least one material selected from a group consisting of hafnium (Hf), zirconium (Zr), aluminum (Al), tantalum (Ta), titanium (Ti), yttrium (Y), tungsten (W), and lanthanoids. For example, the fixed charge layer 82 may be a hafnium oxide layer or an aluminum fluoride layer. Due to the presence of the fixed charge layer 82, holes may accumulate near the second surface 20b. This may make it possible to effectively prevent or reduce the likelihood of the image sensor from suffering from a dark current and/or a white spot.

A buffer layer 84 may be provided on the fixed charge layer 82. In some embodiments, the buffer layer 84 may serve as a planarization layer or a protection layer. The buffer layer 84 may include, for example, a silicon oxide layer and/or a silicon nitride layer. In certain embodiments, the buffer layer 84 may be omitted.

Color filters CF and a micro lens ML may be provided on the buffer layer 84 (in particular, on each unit pixel UP). The color filters CF may be arranged in a matrix form to constitute a color filter array. As an example, the color filters CF may be configured to form a Bayer pattern including red, green, and blue filters. As another example, the color filters CF may be configured to include yellow, magenta, and cyan filters. In certain embodiments, light may be incident into the photoelectric conversion part PD through the micro lens ML, the color filters CF, the buffer layer 84, the fixed charge layer 82, and the second surface 20b.

As shown in FIGS. 4 and 5, each unit pixel UP may include a pair of the photoelectric conversion parts PD, which are disposed to share the color filters CF and the micro lens ML. This means that electrical signals to be output from each unit pixel UP are generated from light of the same color. In other words, electrical signals, which are respectively output from the photoelectric conversion parts PD (or the sub-pixels Px) of each unit pixel UP, may originate from light of the same color. Accordingly, by collectively processing the electrical signals to be respectively output from the sub-pixels Px of each unit pixel UP (for example, by adding intensities of the electric signals), it is possible to obtain image information. In the meantime, there may be a variation in sensitivity or charge storing ability of the photoelectric conversion parts PD. This means that saturation of photo charges (e.g., electrons) may occur early in one of the photoelectric conversion parts PD, before the others. In the case where an amount of generated photo charges is beyond the ability of the photoelectric conversion part PD to store such photo charges, some of the photo charges may be moved to an unintended region (e.g., to other unit pixel UP or a floating diffusion region); that is, some of the photo charges may be lost. By contrast, according to example embodiments of the inventive concept, a region (e.g., the first portion 24) with a relatively-low potential barrier may be formed between adjacent ones of the photoelectric conversion parts PD of each unit pixel UP, and this may make it possible to allow photo charges, which are overflown from one of the photoelectric conversion parts PD, to be transferred to an adjacent one of the photoelectric conversion parts PD, when an amount of generated photo charges is beyond the charge-storing ability of the photoelectric conversion part PD. Furthermore, this may make it possible to realize an improved relationship or linearity in intensity between the incident light and the electric signals obtained from the sub-pixels Px and thereby to prevent or reduce the likelihood of the image sensor from suffering from image distortion.

In addition, because the deep device isolation layers 62 and 64, whose refractive index is different from that of the substrate 20, are provided between the unit pixels UP and between the sub-pixels Px, it is possible to improve cross-talk and color reproducibility characteristics of the image sensor.

Each of electrical signals output from the photoelectric conversion parts PD of the unit pixel UP may be used for a phase-difference AF operation of the auto-focus image sensor. Hereinafter, an auto-focusing function of the auto-focus image sensor will be described in more detail.

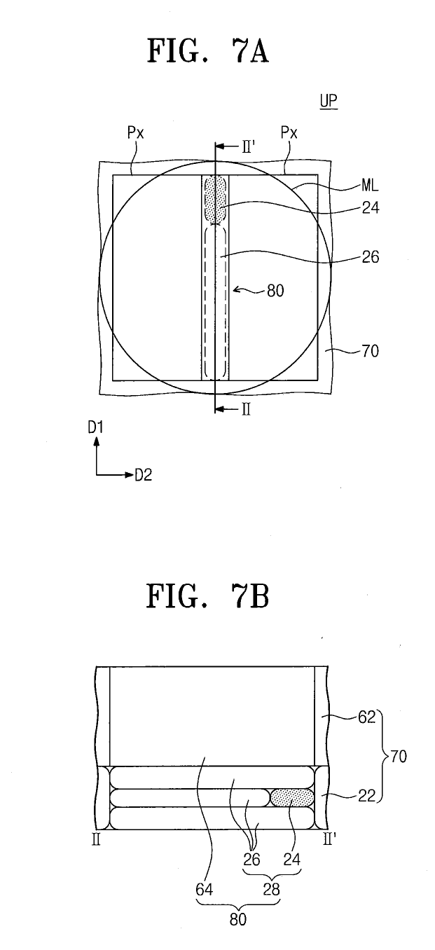

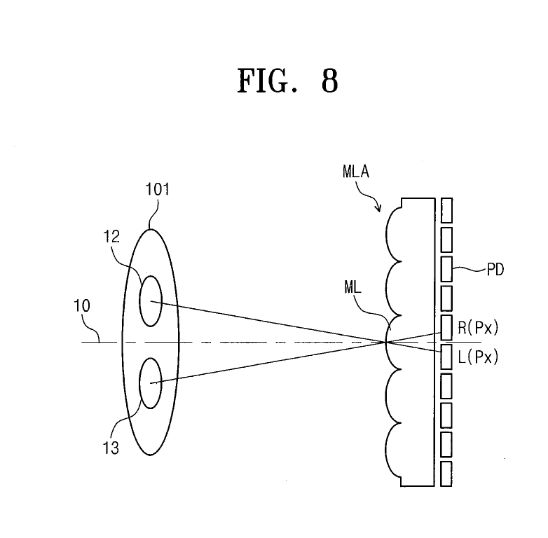

FIG. 8 is a schematic diagram illustrating a phase-difference auto-focus operation of an auto-focus image sensor. FIG. 9A is a graph illustrating a spatial variation in phase of signals that are output from the sub-pixels Px in an out-of-focus state, and FIG. 9B is a graph illustrating a spatial variation in phase of signals that are output from the sub-pixels Px in an in-focus state.

Referring to FIG. 8, light from a subject may be incident into a first sub-pixel R and a second sub-pixel L through the imaging lens 101 and a micro lens array MLA. In some embodiments, the imaging lens 101 may include an upper pupil 12, which is positioned above an optical axis 10 of the imaging lens 101 to guide the light to the second sub-pixel L, and a lower pupil 13, which is positioned below the optical axis 10 of the imaging lens 101 to guide the light to the first sub-pixel R. As described above, the first sub-pixel R and the second sub-pixel L may be configured to share the micro lens ML. In other words, the first and second sub-pixels R and L may constitute each of the unit pixels UP and the photoelectric conversion part PD may be disposed in each of the sub-pixels Px. In each of the unit pixels UP, the photoelectric conversion parts PD may be spaced apart from each other, when viewed in a plan view, and there may be a difference in phase of the light incident into the photoelectric conversion parts PD. The difference in phase of the light incident into the photoelectric conversion parts PD may be used to adjust or set a focal point of the image.

FIGS. 9A and 9B show intensities of signals that are output from the first and second sub-pixels R and L and are measured along a specific direction of the micro lens array MLA. In FIGS. 9A and 9B, the horizontal axis represents positions of the sub pixels and the vertical axis represents intensities of output signals. Referring to FIGS. 9A and 9B, there is no substantial difference in shape between the solid- and dotted-line curves R and L that were respectively obtained from the first and second sub-pixels R and L, whereas there is a difference in imaging position or phase between the solid- and dotted-line curves R and L. The phase difference may result from the eccentric arrangement of the pupils 12 and 13 of the imaging lens 101 and the consequent difference in imaging position of the incident light. For example, when the image sensor is in an out-of-focus state, there may be a phase difference, as shown in FIG. 9A, and when the image sensor is in an in-focus state, there may be no substantial phase difference as shown in FIG. 9B. Furthermore, this result may be used to determine which direction the difference of the focal point occurs. For example, in the case where the focal point is located in front of a subject, signals output from the first sub-pixel R may have a phase shifted leftward from that in a focused state and signals output from the second sub-pixel L may have a phase shifted rightward from that in the focused state. By contrast, in the case where the focal point is located behind a subject, signals output from the first sub-pixel R may have a phase shifted rightward from that in a focused state and signals output from the second sub-pixel L may have a phase shifted leftward from that in the focused state. A difference in phase shift between the signals output from the first and second sub-pixels R and L may be used to calculate deviation between the focal points.

According to example embodiments of the inventive concept, an additional pixel (hereinafter, a focal-point-detecting pixel) (not shown) for detecting a focal point of image may not be provided in the auto-focus image sensor. Here, the focal-point-detecting pixel may make it possible to adjust a focal point of the unit pixel UP, but may not be used to obtain an image of a subject. This means that as more focal-point-detecting pixels are used, less unit pixels UP are used. According to example embodiments of the inventive concept, because there is no focal-point-detecting pixel, it may be possible to increase resolution of the auto-focus image sensor.

Hereinafter, a method of fabricating an auto-focus image sensor according to example embodiments of the inventive concept will be described with reference to the accompanying drawings.

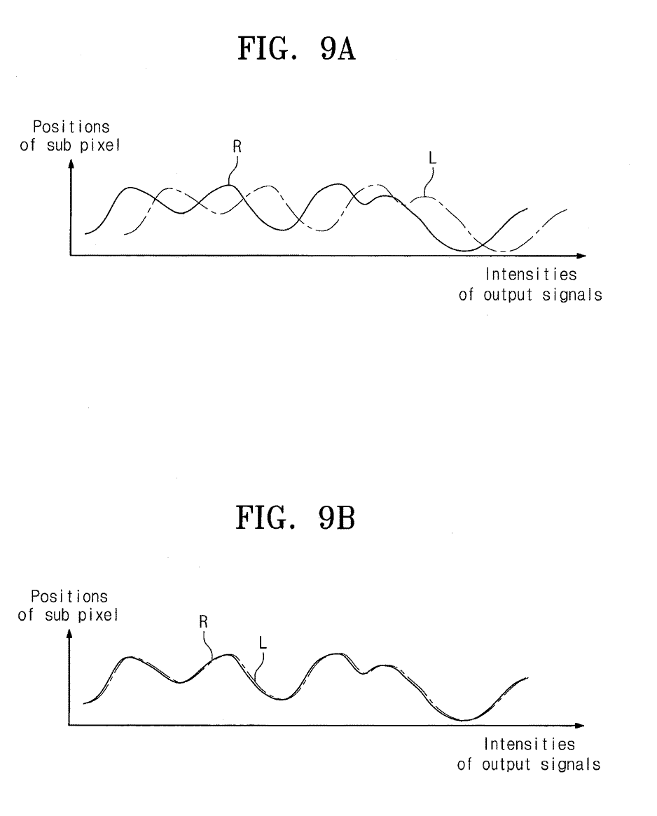

FIGS. 10 through 15 are sectional views taken along line I-I′ of FIG. 4 to illustrate a method of fabricating an auto-focus image sensor, according to example embodiments of the inventive concept.

Referring to FIG. 10, the substrate 20 may be provided to have the first and second surfaces 20a and 20b facing each other. The substrate 20 may be a silicon wafer, a silicon wafer provided with a silicon epitaxial layer, or a silicon-on-insulator (SOI) wafer. Ion implantation processes using an ion injection mask (not shown) may be performed on the first surface 20a of the substrate 20 to form the first doped region 22 and the second doped region 28. The first and second doped regions 22 and 28 may be doped to have a first conductivity type (e.g., p-type). In some embodiments, the second doped region 28 may include a plurality of stacked impurity regions. As an example, the second doped region 28 may be formed to include the first portion 24, which is lightly doped with first conductivity type impurities, and the second portions 26, which are heavily doped with first conductivity type impurities to have a higher impurity concentration than the first portion 24. In addition, the first portion 24 may be formed to have a doping concentration lower than that of the first doped region 22. The formation of the second doped region 28 may include a plurality of ion implantation processes performed with different injection energies. The second doped region 28 may be formed to have a line-shaped structure extending in the first direction D1. The first doped region 22 may be formed to define the unit pixels UP in the substrate 20, and the second doped region 28 may be formed to define the sub-pixels Px in each of the unit pixels UP.

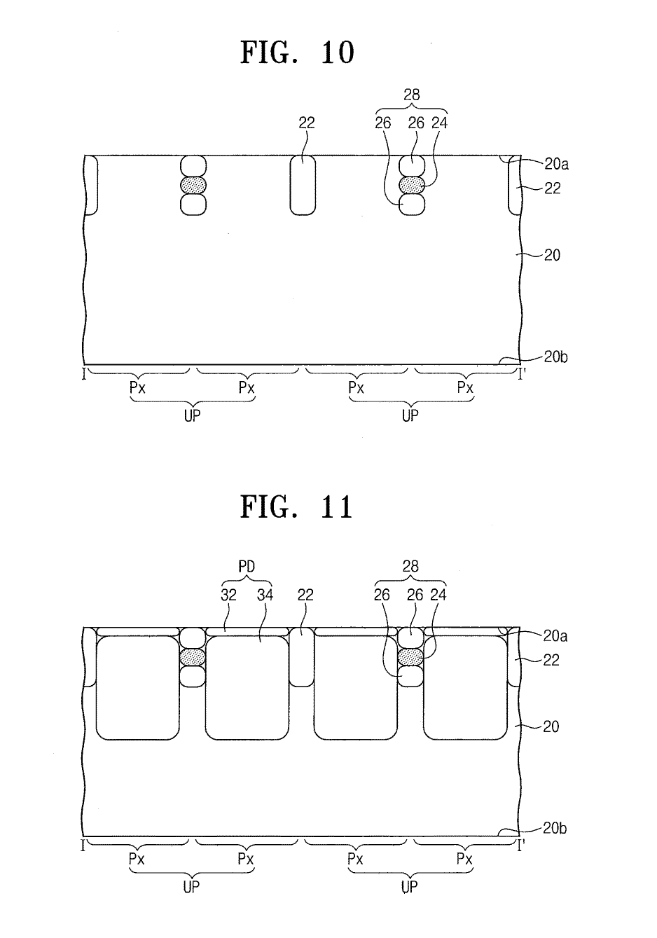

Referring to FIG. 11, ion implantation processes may be performed to form the first and second impurity regions 32 and 34 in the sub-pixels Px of the substrate 20. In each of the sub-pixels Px, the first and second impurity regions 32 and 34 may serve as the photoelectric conversion part PD. The first impurity region 32 may be doped to have a first conductivity type (e.g., p-type), and the second impurity region 34 may be doped to have a second conductivity type (e.g., n-type). The first impurity region 32 may be formed adjacent to the first surface 20a of the substrate 20, and the second impurity region 34 may be formed spaced apart from the first surface 20a of the substrate 20. In addition, the second impurity region 34 may be formed in a region deeper than the first and second doped regions 22 and 28. Although not shown, the transistors TX, RX, SX, and DX described with reference to FIG. 3A or 3B may be formed on the first surface 20a.

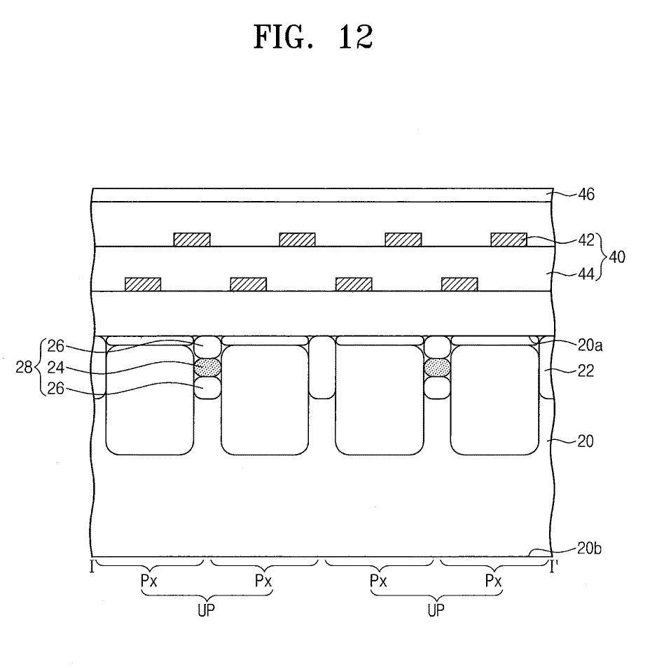

Referring to FIG. 12, the interconnection structure 40 may be formed on the first surface 20a. The interconnection structure 40 may include the interlayered insulating layers 44 and the interconnection layers 42, which are stacked one on another. The protection layer 46 may be formed on the interconnection structure 40. In certain embodiments, the protection layer 46 may serve as a passivation layer and/or a supporting substrate.

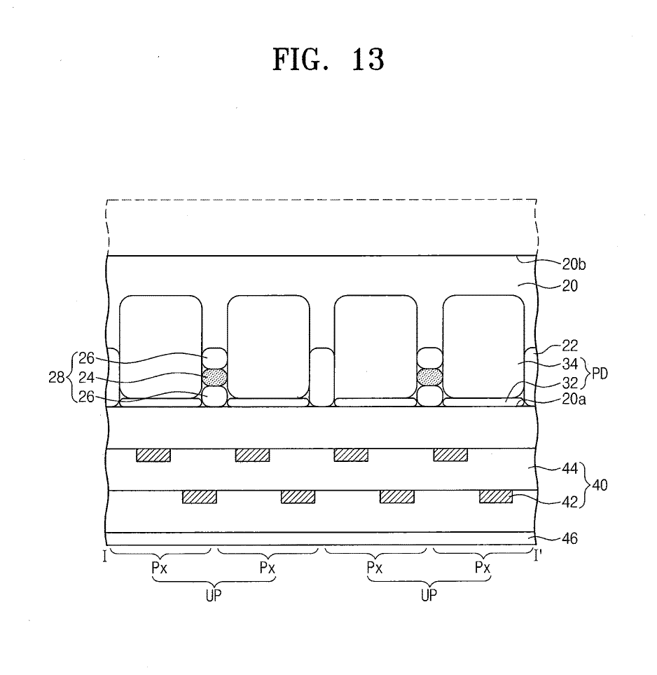

Referring to FIG. 13, the substrate 20 may be inverted to allow the second surface 20b to be oriented in an upward direction. Thereafter, a back-grinding process may be performed on the second surface 20b to remove a portion of the substrate 20. In some embodiments, the back-grinding process may be performed so as not to expose the second impurity region 34.

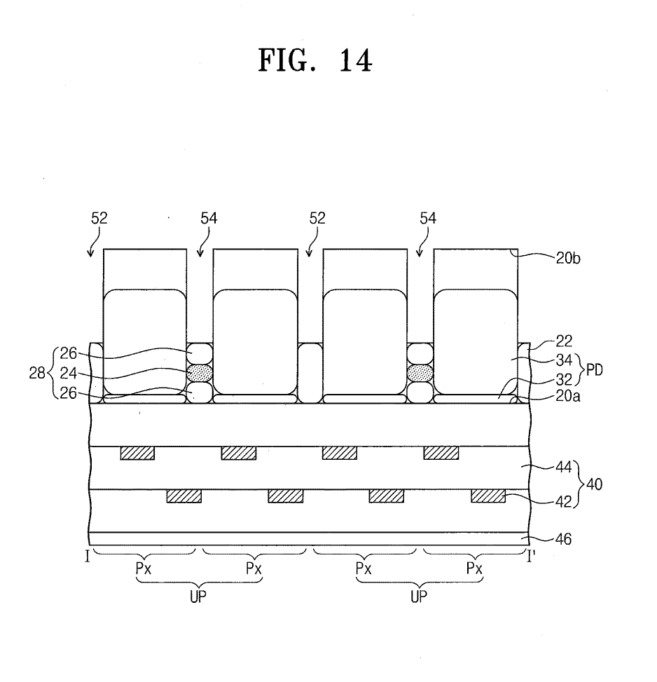

Referring to FIG. 14, a mask pattern (not shown) may be formed on the second surface 20b of the substrate 20, and an etching process using the mask pattern as an etch mask may be performed to etch the substrate 20. As a result, the first deep trench 52 and the second deep trench 54 may be formed to expose the first doped region 22 and the second doped region 28, respectively. In some embodiments, the first deep trench 52 and the second deep trench 54 may be simultaneously formed. The first deep trench 52 may be connected to the second deep trench 54.

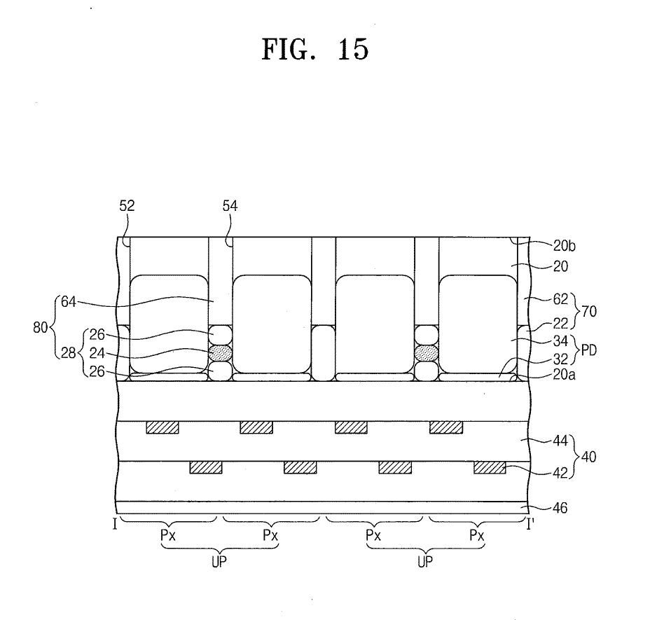

Referring to FIG. 15, an insulating layer may be formed on the second surface 20b to fill the first deep trench 52 and the second deep trench 54 and a planarization process may be performed to expose the second surface 20b. As a result of the planarization process, the first deep device isolation layer 62 may be formed in the first deep trench 52 and the second deep device isolation layer 64 may be formed in the second deep trench 54. The first and second deep device isolation layers 62 and 64 may be formed of substantially the same material. As an example, the first and second deep device isolation layers 62 and 64 may be formed of or include at least one of silicon oxide, silicon nitride, or silicon oxynitride layer.

Referring back to FIG. 5, the fixed charge layer 82 may be formed on the second surface 20b of the substrate 20. The fixed charge layer 82 may be formed using a chemical vapor deposition or atomic layer deposition method. The fixed charge layer 82 may be formed of an oxygen-containing metal layer, whose oxygen content is lower than its stoichiometric ratio, or a fluorine-containing metal layer, whose fluorine content ratio is lower than its stoichiometric ratio. The fixed charge layer 82 may be formed of a metal oxide or metal fluoride including at least one material selected from a group consisting of hafnium (Hf), zirconium (Zr), aluminum (Al), tantalum (Ta), titanium (Ti), yttrium (Y), tungsten (W), and lanthanoids. In some embodiments, a subsequent process after the formation of the fixed charge layer 82 may be performed at a process temperature that is lower than or equal to that used in the formation of the fixed charge layer 82. This may allow the fixed charge layer 82 to have an oxygen content lower than its stoichiometric ratio and thereby to be in a negatively-charged state. The buffer layer 84 may be formed on the fixed charge layer 82. The buffer layer 84 may be formed of or include at least one of a silicon oxide layer or a silicon nitride layer. A color filter CF and the micro lens ML may be sequentially formed on each of the unit pixel regions UP.

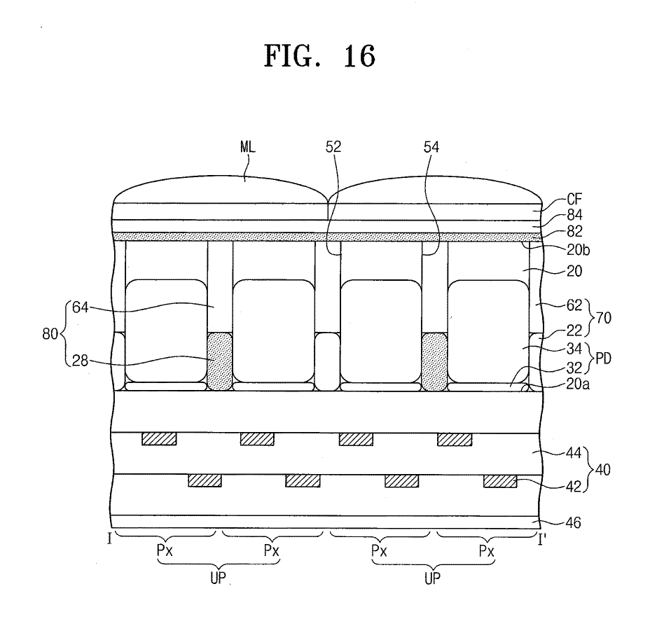

FIG. 16 is a sectional view taken along line I-I′ of FIG. 4 to illustrate an auto-focus image sensor according to example embodiments of the inventive concept.

Referring to FIG. 16, in the auto-focus image sensor according to example embodiments of the inventive concept, the first portion 24 described with reference to FIG. 5 may be solely used as the second doped region 28 of the sub-pixel separation part 80. In some embodiments, the second doped region 28 may have an impurity concentration lower than that of the first doped region 22 and may have the first conductivity type. The second doped region 28 may include opposite end portions that are in contact with the first surface 20a of the substrate 20 and the second deep device isolation layer 64, respectively. The afore-described structure of the second doped region 28 may allow photo charges (e.g., electrons) generated in the photoelectric conversion parts PD to be transmitted through a current path with an increased sectional area. Except for these embodiments, the auto-focus image sensor may be configured to have substantially the same features as that described with reference to FIGS. 4 and 5, and a detailed description thereof will be omitted.

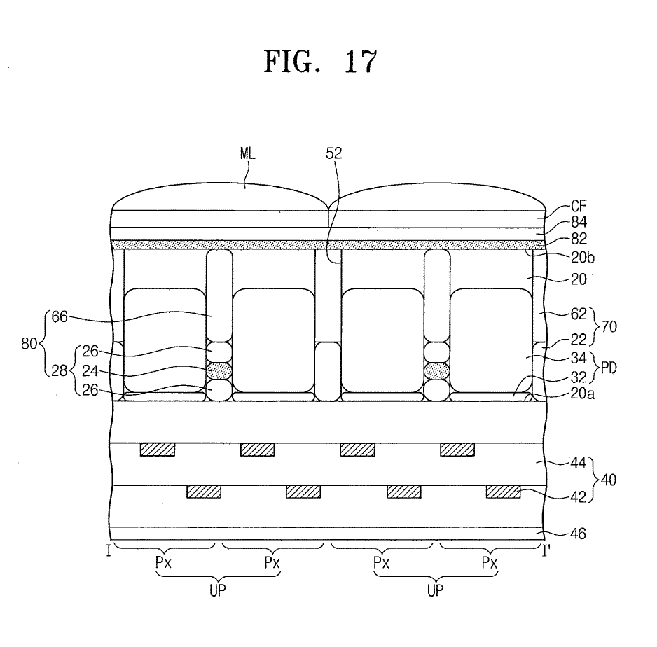

FIG. 17 is a sectional view taken along line I-I′ of FIG. 4 to illustrate an auto-focus image sensor according to example embodiments of the inventive concept.

Referring to FIG. 17, the sub-pixel separation part 80 of the auto-focus image sensor may include or comprise the second doped region 28 adjacent to the first surface 20a and a third doped region 66 adjacent to the second surface 20b and in contact with the second doped region 28. For example, in the auto-focus image sensor of FIG. 17, the third doped region 66 may be provided in place of the second deep device isolation layer 64 of the sub-pixel separation part 80 of FIG. 5. The second doped region 28 may have the same or similar technical features as that of FIGS. 4 and 5. The third doped region 66 may be doped with first conductivity type impurities (e.g., p-type impurities). The third doped region 66 may have an impurity concentration higher than that of the first portion 24 of the second doped region 28. In addition, an impurity concentration of the third doped region 66 may be substantially equal to or lower than that of the first doped region 22. The third doped region 66 may be formed by performing an ion implantation process on the structure of FIG. 10. Except for these embodiments, the auto-focus image sensor may be configured to have substantially the same features as that described with reference to FIGS. 4 and 5, and a detailed description thereof will be omitted.

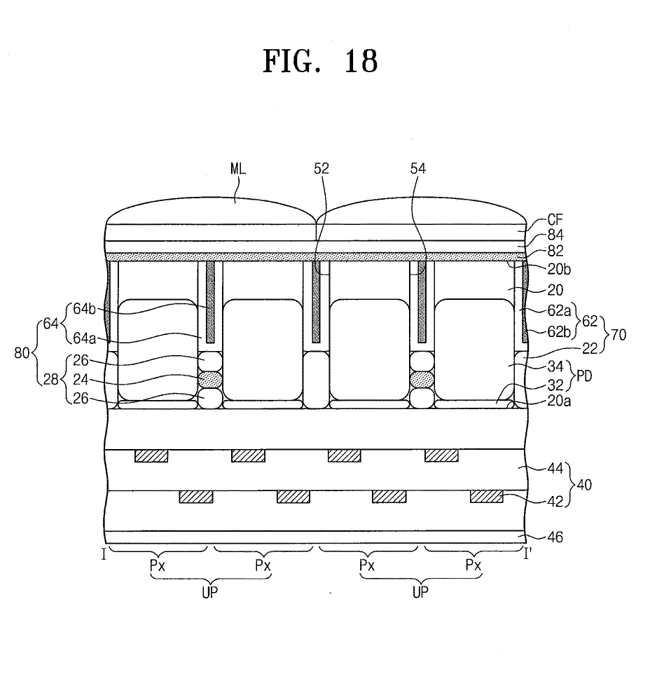

FIG. 18 is a sectional view taken along line I-I′ of FIG. 4 to illustrate an auto-focus image sensor according to example embodiments of the inventive concept.

Referring to FIG. 18, in the auto-focus image sensor according to example embodiments of the inventive concept, the first deep device isolation layer 62 may include or consist of a first insulating gapfill layer 62a and a first poly silicon pattern 62b disposed in the first insulating gapfill layer 62a. Furthermore, the second deep device isolation layer 64 may include or comprise a second insulating gapfill layer 64a and a second poly silicon pattern 64b disposed in the second insulating gapfill layer 64a. The first and second insulating gapfill layers 62a and 64a may be formed of substantially the same material. As an example, the first and second insulating gapfill layers 62a and 64a may be formed of or include at least one of silicon oxide, silicon nitride, or silicon oxynitride layer. The first and second polysilicon patterns 62b and 64b may have substantially the same thermal expansion coefficient as that of the substrate 20 or a silicon layer, and this may make it possible to reduce a physical stress, which may be caused by a difference in thermal expansion coefficient between materials. Except for these embodiments, the auto-focus image sensor may be configured to have substantially the same features as that described with reference to FIGS. 4 and 5, and a detailed description thereof will be omitted.

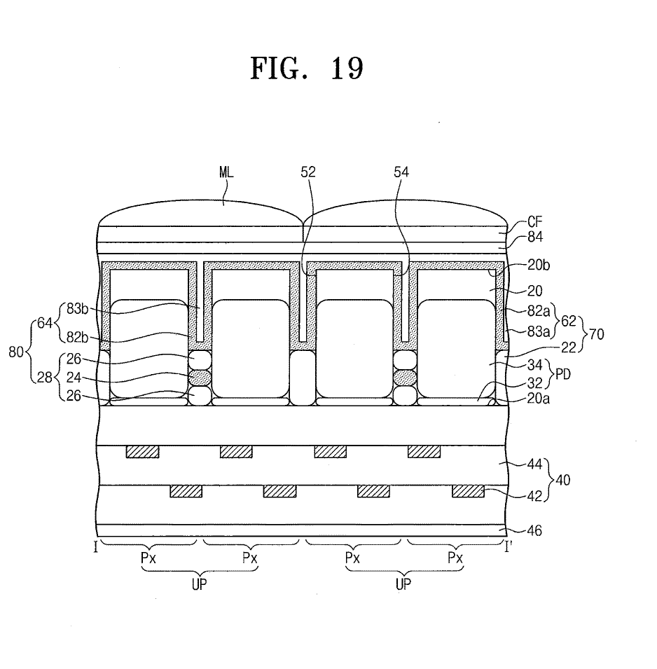

FIG. 19 is a sectional view taken along line I-I′ of FIG. 4 to illustrate an auto-focus image sensor according to example embodiments of the inventive concept.

Referring to FIG. 19, in the auto-focus image sensor according to example embodiments of the inventive concept, the first deep device isolation layer 62 may include or comprise a first fixed charge layer 82a and a first insulating layer 83a. Furthermore, the second deep device isolation layer 64 may include or comprise a second fixed charge layer 82b and a second insulating layer 83b. The first and second fixed charge layers 82a and 82b may be formed of or include a material that is substantially the same as the fixed charge layer 82 described with reference to FIGS. 4 and 5. For example, each of the first and second fixed charge layers 82a and 82b may be formed of a metal oxide or metal fluoride including at least one material selected from a group consisting of hafnium (Hf), zirconium (Zr), aluminum (Al), tantalum (Ta), titanium (Ti), yttrium (Y), tungsten (W), and lanthanoids. As an example, each of the first and second fixed charge layers 82a and 82b may be a hafnium oxide layer or an aluminum fluoride layer. The first and second insulating layers 83a and 83b may be a silicon oxide layer or a silicon nitride layer. The first and second fixed charge layers 82a and 82b may be extended and connected to each other on the second surface 20b of the substrate 20. Similarly, the first and second insulating layers 83a and 83b may be extended and connected to each other on the second surface 20b of the substrate 20. The first and second fixed charge layers 82a and 82b may be formed to cover the second surface 20b as well as a side surface of the photoelectric conversion part PD, and this structure of the first and second fixed charge layers 82a and 82b may contribute to improve a dark current property of the image sensor. Except for these embodiments, the auto-focus image sensor may be configured to have substantially the same features as that described with reference to FIGS. 4 and 5, and a detailed description thereof will be omitted.

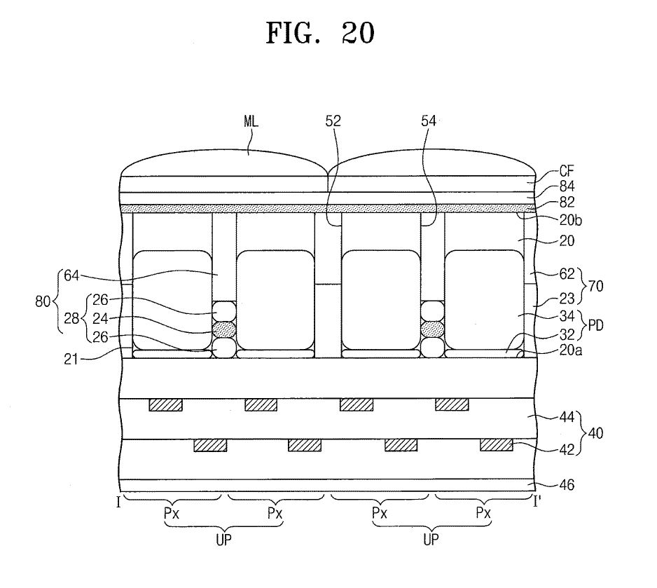

FIG. 20 is a sectional view taken along line I-I′ of FIG. 4 to illustrate an auto-focus image sensor according to example embodiments of the inventive concept.

Referring to FIG. 20, in the auto-focus image sensor according to example embodiments of the inventive concept, the pixel separation part 70 may include or comprise the first deep device isolation layer 62 adjacent to the second surface 20b and the third deep device isolation layer 23 adjacent to the first surface 20a and in contact with the first deep device isolation layer 62. For example, in the auto-focus image sensor of FIG. 20, the third deep device isolation layer 23 may be provided in place of the first doped region 22 of the sub-pixel separation part 80 of FIG. 5. The first deep device isolation layer 62 may have the same or similar technical features as that of FIGS. 4 and 5. The third deep device isolation layer 23 may be disposed in a third deep trench 21, which may be formed to penetrate the substrate 20 in a direction from the first surface 20a of the substrate 20 toward the second surface 20b. For example, the third deep device isolation layer 23 may be formed by forming the third deep trench 21 on the structure of FIG. 10 and then filling the third deep trench 21 with an insulating material. The third deep device isolation layer 23 may be formed of an insulating material whose refractive index is different from that of the substrate 20. As an example, the third deep device isolation layer 23 may be formed of or include at least one of silicon oxide, silicon nitride, or silicon oxynitride layer. An interface between the first and third deep device isolation layers 62 and 23 may be positioned closer to the second surface 20b of the substrate 20 than a bottom surface of the second deep device isolation layer 64 in contact with the second doped region 28. The deep device isolation layers 23 and 62 may be formed in the deep trenches 21 and 52, respectively, and this may make it possible to relieve the burden of etching processes for forming the deep trenches 21 and 52, respectively. In addition, it is possible to reduce depths of the deep trenches 21 and 52, on which a gap-filling process will be performed, and thereby to improve a gap-fill property of the deep device isolation layers 23 and 62. Accordingly, it is possible to realize a highly-reliable auto-focus image sensor. Except for these embodiments, the auto-focus image sensor may be configured to have substantially the same features as that described with reference to FIGS. 4 and 5, and a detailed description thereof will be omitted.

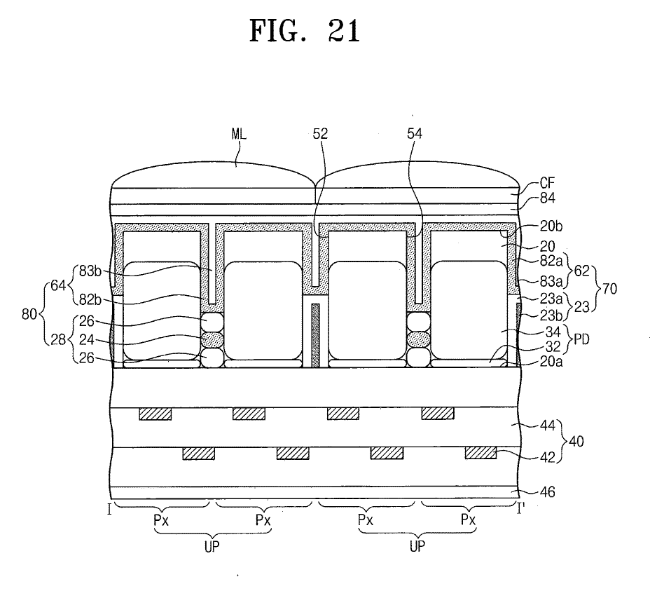

FIG. 21 is a sectional view taken along line I-I′ of FIG. 4 to illustrate an auto-focus image sensor according to example embodiments of the inventive concept.

Referring to FIG. 21, in the auto-focus image sensor according to example embodiments of the inventive concept, the pixel separation part 70 may include or comprise the first deep device isolation layer 62 adjacent to the second surface 20b and the third deep device isolation layer 23 adjacent to the first surface 20a and in contact with the first deep device isolation layer 62. The third deep device isolation layer 23 may include or comprise a third insulating gapfill layer 23a and a third poly silicon pattern 23b provided in the third insulating gapfill layer 23a. The third deep device isolation layer 23 may be disposed in the third deep trench 21, which may be formed to penetrate the substrate 20 in a direction from the first surface 20a of the substrate 20 toward the second surface 20b. The first deep device isolation layer 62 may include or comprise the first fixed charge layer 82a and the first insulating layer 83a described with reference to FIG. 19. The second deep device isolation layer 64 of the sub-pixel separation part 80 may include or comprise the second fixed charge layer 82b and the second insulating layer 83b described with reference to FIG. 19. The third insulating gapfill layer 23a may be formed of or include at least one of silicon oxide, silicon nitride, or silicon oxynitride layer. The third poly silicon pattern 23b may have substantially the same thermal expansion coefficient as that of the substrate 20 or a silicon layer, and this may make it possible to reduce a physical stress, which may be caused by a difference in thermal expansion coefficient between materials. Except for these embodiments, the auto-focus image sensor may be configured to have substantially the same features as that described with reference to FIGS. 4 and 5, and a detailed description thereof will be omitted.

According to example embodiments of the inventive concept, an auto-focus image sensor may include a plurality of unit pixels, and each of the unit pixels may include a plurality of photoelectric conversion parts configured to detect a phase difference of incident light. This may make it possible to omit additional focal-point-detecting pixels (not shown) from an auto-focus image sensor and thereby to realize a high resolution image sensor. In addition, a region with a relatively low potential barrier may be formed between adjacent ones of the photoelectric conversion parts, and this may make it possible to allow photo charges, which are overflowed from one of the photoelectric conversion parts, to be transferred to an adjacent one of the photoelectric conversion parts, when an amount of generated photo charges is beyond the charge-storing ability of the photoelectric conversion part. Furthermore, this may make it possible to realize an improved (e.g., more linear) relationship in intensity between incident light and image signals obtained from each unit pixel. Accordingly, it may be possible to prevent the image sensor from suffering from image distortion.

In addition, deep device isolation layers may be provided between the unit pixels and between the sub-pixels, and the deep device isolation layers may have a refractive index different from that of a substrate. This may make it possible to improve cross-talk and color reproducibility characteristics of the image sensor.

While example embodiments of the inventive concepts have been particularly shown and described, it will be understood by one of ordinary skill in the art that variations in form and detail may be made therein without departing from the spirit and scope of the attached claims.

1. An auto-focus image sensor, comprising:
a substrate with unit pixels, the substrate having a first surface and a second surface facing the first surface and serving as a light-receiving surface;
a pixel separation part provided in the substrate to separate the unit pixels from each other;
at least one pair of photoelectric conversion parts provided in each of the unit pixels of the substrate; and
a sub-pixel separation part interposed between the at least one pair of the photoelectric conversion parts that are positioned adjacent to each other,
wherein at least a portion of the pixel separation part comprises a material whose refractive index is different from that of the substrate, and
the sub-pixel separation part comprises a portion that is configured to allow photo charges generated in the at least one pair of the photoelectric conversion parts to be transmitted therethrough.

2. The auto-focus image sensor of claim 1, wherein the pixel separation part is configured to penetrate the substrate from the first surface to the second surface,
the pixel separation part comprises a first doped region adjacent to the first surface and a first deep device isolation layer adjacent to the second surface and in contact with the first doped region,
the first doped region is doped to have a first conductivity type, and
the first deep device isolation layer comprises a material whose refractive index is different from that of the substrate.

3. The auto-focus image sensor of claim 2, wherein each of the at least one pair of the photoelectric conversion parts comprises:
a first impurity region, which is formed adjacent to the first surface and is doped to have the first conductivity type; and
a second impurity region, which is formed spaced apart from the first surface and is doped to have a second conductivity type different from the first conductivity type,
wherein a top surface of the second impurity region adjacent to the second surface is farther from the first surface than an interface between the first doped region and the first deep device isolation layer.

4. The auto-focus image sensor of claim 2, wherein the sub-pixel separation part comprises a second doped region, which is disposed adjacent to the first surface and is doped to have the first conductivity type, and
at least a portion of the second doped region has a lower concentration of impurities of the first conductivity type than the first doped region.

5. The auto-focus image sensor of claim 4, wherein the sub-pixel separation part further comprises a second deep device isolation layer disposed adjacent to the second surface and in contact with the second doped region, and
the second deep device isolation layer comprises substantially a same material as the first deep device isolation layer.

6. The auto-focus image sensor of claim 4, wherein the sub-pixel separation part further comprises a third doped region disposed adjacent to the second surface and in contact with the second doped region, and
the third doped region is doped to have the first conductivity type and has a higher concentration of impurities of the first conductivity type than the at least a portion of the second doped region.

7.-11. (canceled)

12. The auto-focus image sensor of claim 11, wherein each of the first and second fixed charge layers is formed of a metal oxide or metal fluoride including at least one material selected from a group consisting of hafnium (Hf), zirconium (Zr), aluminum (Al), tantalum (Ta), titanium (Ti), yttrium (Y), tungsten (W), and lanthanoids.

13. The auto-focus image sensor of claim 1, wherein the pixel separation part comprises a first deep device isolation layer adjacent to the second surface and a third deep device isolation layer adjacent to the first surface and in contact with the first deep device isolation layer.

14. (canceled)

15. The auto-focus image sensor of claim 13, wherein the sub-pixel separation part comprises a second doped region, which is disposed adjacent to the first surface and is doped to have a first conductivity type, and a second deep device isolation layer, which is disposed adjacent to the second surface and in contact with the second doped region, and
the second deep device isolation layer comprises substantially a same material as the first deep device isolation layer.

16. The auto-focus image sensor of claim 15, wherein an interface between the first deep device isolation layer and the third deep device isolation layer is closer to the second surface than a bottom surface of the second deep device isolation layer in contact with the second doped region.

17.-20. (canceled)

21. An auto-focus image sensor, comprising:
a substrate having first and second surfaces facing each other, the substrate comprising unit pixels, each of which comprises at least one pair of sub-pixels configured to detect a difference in phase of light incident through the second surface;
a photoelectric conversion part in each of the at least one pair of the sub-pixels of the substrate;
a pixel separation part configured to penetrate the substrate from the first surface to the second surface and to separate the unit pixels from each other;
a sub-pixel separation part configured to penetrate the substrate from the first surface to the second surface and to separate the at least one pair of the sub-pixels from each other; and
a fixed charge layer on the second surface,
wherein at least a portion of the pixel separation part comprises a material whose refractive index is different from that of the substrate, and
each of the unit pixels is configured to collectively process electrical signals, which are respectively output from the at least one pair of the sub-pixels, to obtain image information.

22. The auto-focus image sensor of claim 21, wherein the pixel separation part comprises a first doped region adjacent to the first surface and a first deep device isolation layer adjacent to the second surface and in contact with the first doped region,
the first doped region is doped to have a first conductivity type, and
the first deep device isolation layer comprises a material whose refractive index is different from that of the substrate.

23. The auto-focus image sensor of claim 22, wherein the sub-pixel separation part comprises:
a second doped region, which is disposed adjacent to the first surface and is doped to have the first conductivity type; and
a second deep device isolation layer, which is disposed adjacent to the second surface and in contact with the second doped region,
wherein at least a portion of the second doped region has a lower concentration of impurities of the first conductivity type than the first doped region.

24. The auto-focus image sensor of claim 23, wherein the second deep device isolation layer comprises substantially a same material as the first deep device isolation layer.

25. The auto-focus image sensor of claim 23, wherein the sub-pixel separation part is configured to allow photo charges generated in the at least one pair of the photoelectric conversion parts to be transmitted through the at least a portion of the second doped region.

26.-27. (canceled)

28. The auto-focus image sensor of claim 21, wherein the pixel separation part comprises a first deep device isolation layer adjacent to the second surface and a third deep device isolation layer adjacent to the first surface and in contact with the first deep device isolation layer, and
each of the first deep device isolation layer and the third device isolation layer comprises a material whose refractive index is different from that of the substrate.

29. The auto-focus image sensor of claim 28, wherein the sub-pixel separation part comprises a second doped region, which is disposed adjacent to the first surface and is doped to have a first conductivity type, and a second deep device isolation layer, which is disposed adjacent to the second surface and in contact with the second doped region, and
the second deep device isolation layer.

30. An image sensor, comprising:
a substrate having a unit pixel disposed therein;
the unit pixel comprising first and second photoelectric conversion parts;
a separation part disposed between the first and second photoelectric conversion parts that is configured to provide a current path for charge to transfer between the first and second photoelectric conversion parts responsive to incident light received at the unit pixel; and
a unit pixel isolation region that surrounds the unit pixel when the substrate is viewed from a plan view,
wherein at least a portion of the unit pixel isolation region includes an insulating material.

31. The auto-focus image sensor of claim 30, wherein the separation part comprises:
a doped region; and
an isolation layer disposed on the doped region;
wherein the doped region is configured to provide the current path for the charge to transfer between the first and second photoelectric conversion parts.

32. The auto-focus image sensor of claim 31, wherein the doped region comprises:
a first portion; and
a second portion comprising a plurality of layers, the first portion being disposed between ones of the plurality of layers of the second portion;
wherein the first portion has a doping concentration that is less than a doping concentration of the second portion.

33.-34. (canceled)
